(19) United States
(12) Patent Application Publication
(10) Pub. No.: US 2015/0125792 A1
(43) Pub. Date: May 7, 2015

(54) PHTHALOCYANINE PIGMENT AND PIGMENT DISPERSION, INK AND COLOR FILTER RESIST COMPOSITION CONTAINING SAME

(71) Applicant: CANON KABUSHIKI KAISHA, Tokyo (JP)

(72) Inventors: Ryuji Higashi, Kawasaki-shi (JP); Akiko Kitao, Kawasaki-shi (JP); Taichi Shintou, Saitama-shi (JP); Takeshi Miyazaki, Ebina-shi (JP)

(21) Appl. No.: 14/407,646

(22) PCT Filed: Aug. 21, 2013
(86) PCT No.: PCT/JP2013/072932

§ 371 Date: Dec. 12, 2014

(30) Foreign Application Priority Data
Aug. 22, 2012 (JP) 2012-183475

(51) Int. Cl. C09B 47/04; G03F 7/00; C09B 47/30

(52) U.S. Cl. CPC C09B 47/04; C09B 47/30; G03F 7/0007
USPC 430/270.1; 540/123; 540/121; 106/410; 106/31.78

(57) ABSTRACT

The present invention provides a phthalocyanine pigment having superior color development property, and a pigment dispersion, an ink and a color filter resist composition containing the phthalocyanine pigment, in which the phthalocyanine pigment having a structure represented by general formula (1), and the pigment dispersion, the ink and the color filter resist composition containing the phthalocyanine pigment.

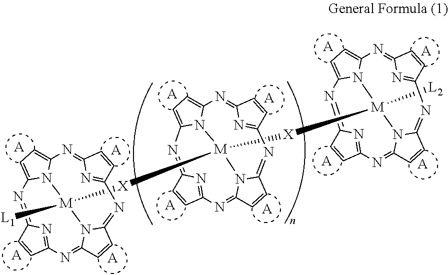

### TECHNICAL FIELD

The present invention relates to a phthalocyanine pigment, and a pigment dispersion, an ink and a color filter resist composition containing that phthalocyanine pigment used in the production processes of paint, ink jet ink, color filters, plastic moldings and the like.

### BACKGROUND ART

There has recently been a growing demand for higher image quality of color images, including those generated by color liquid crystal displays. Color filters are essential for liquid crystal displays to display color, and constitute an important component that influences the performance of those liquid crystal displays.

Known examples of conventional color filter production methods include a dyeing method, printing method, ink jet method and photoresist method. Among these, the photoresist method has recently come to be the mainstream of color filter production methods since it is able to facilitate control and reproducibility of spectral characteristics and enable higher definition patterning due to its high resolution.

In this photoresist method, a phthalocyanine-based pigment is typically used as a cyan-based colorant (see Patent Literature 1 and 2).

Phthalocyanine-based pigments are characterized by being inexpensive and having lightfastness, and are used in a wide range of fields. However, phthalocyanine-based pigments have low color development property, and in fields requiring high levels of color development property such as color filters, examples have been disclosed that use phthalocyanine dye in order to improve on this (see Patent Literature 3 and 4).

On the other hand, in comparison with pigments, dyes have lower lightfastness in general. Thus, there is the need to develop a phthalocyanine-based pigment having even better lightfastness and superior color development property in order to display high-definition images.

### CITATION LIST

### Patent Literature

[PTL 1] Japanese Patent Application Laid-open No. 2009-242687
[PTL 2] WO 2007/088662
[PTL 3] Japanese Patent Application Laid-open No. H05-333207
[PTL 4] Japanese Translation of PCT Application No. 2008-511856

### SUMMARY OF INVENTION

### Technical Problems

The present invention provides solution for the above-mentioned problems. Namely, the present invention provides a phthalocyanine pigment having superior color development property, and a pigment dispersion, an ink and a color filter resist composition containing that phthalocyanine pigment.

### Solution to Problem

The above-mentioned problems are achieved by the inventions indicated below.

A first invention relates to a phthalocyanine pigment having a structure represented by general formula (1) indicated below.

In addition, a second invention relates to a pigment dispersion comprising a dispersion medium and the phthalocyanine pigment represented by general formula (1) indicated below.

Moreover, a third invention relates to an ink containing the above-mentioned pigment dispersion.

Moreover, a fourth invention relates to a color filter resist composition containing the above-mentioned phthalocyanine pigment.

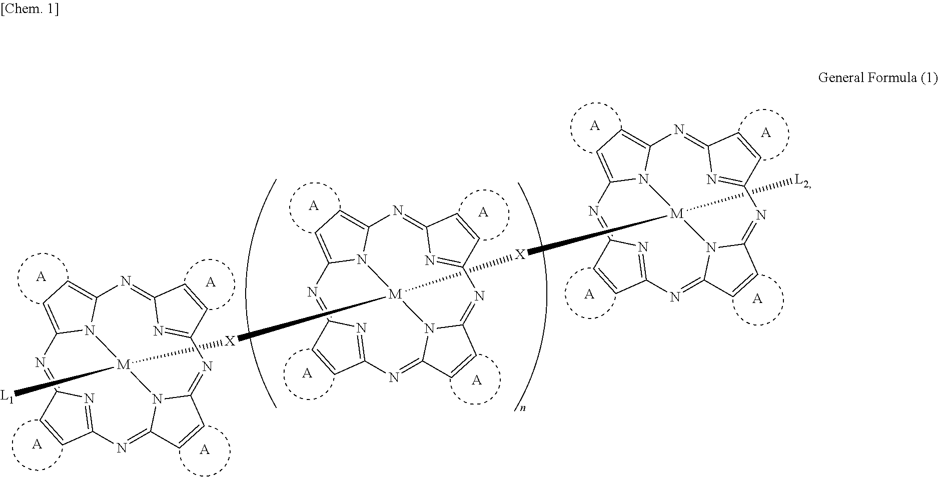

In the above-mentioned general formula (1),

X represents —O—CH₂—R¹—CH₂—O—,

R¹ represents a monocyclic or polycyclic cyclic hydrocarbon group or —CR²R³—,

R² and R³ represent alkyl group,

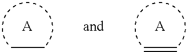

each independently represent a substituted or unsubstituted aryl ring or a heterocycle containing one or two nitrogen atoms,

M represents a metal atom selected from the group consisting of Si, Ge and Sn,

L₁ and L₂ each independently represent a halogen atom, hydroxyl group, —O—CH₂—R⁴—CH₂—OR⁶, —O—CH₂—R⁵—OR⁹ or —OR¹⁶,

R⁴ and R⁵ represent a monocyclic or polycyclic cyclic hydrocarbon group or —CR⁶R⁷—,

R⁶ and R⁷ represent alkyl group,

R⁸ to R¹⁶ each independently represent a hydrogen atom, methyl group or trimethylsilyl group, and

n represents an integer of 1 or more.

### Advantageous Effects of Invention

According to the present invention, a phthalocyanine pigment having superior color development property, and a pigment dispersion, an ink and a color filter resist composition containing the phthalocyanine pigment, can be provided.

Further features of the present invention will become apparent from the following description of exemplary embodiments.

### DESCRIPTION OF EMBODIMENTS

The following provides a more detailed explanation of the present invention by indicating embodiments thereof.

As a result of conducting extensive studies to solve the above-mentioned problems of the background art, the inventors of the present invention found that a phthalocyanine pigment having a structure represented by general formula (1) indicated below has superior color development property. In addition, the inventors of the present invention also found that a pigment dispersion having superior color development property, an ink and a color filter resist composition can be obtained by containing the phthalocyanine pigment, thereby leading to completion of the present invention.

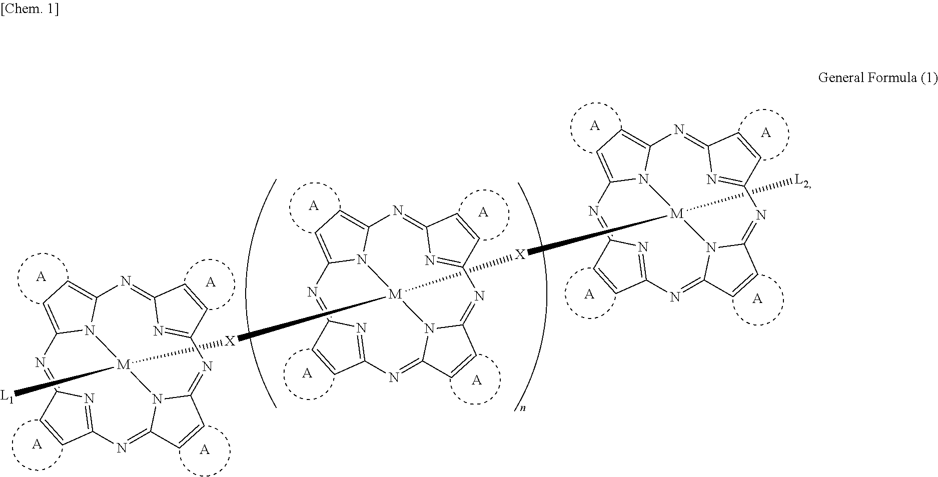

In the above-mentioned general formula (1),

X represents —O—CH₂—R¹—CH₂—O—,

R¹ represents a monocyclic or polycyclic cyclic hydrocarbon group or —CR²R³—,

R² and R³ represent alkyl group,

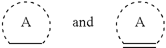

each independently represent a substituted or unsubstituted aryl ring or a heterocycle containing one or two nitrogen atoms,

M represents a metal atom selected from the group consisting of Si, Ge and Sn,

L₁ and L₂ each independently represent a halogen atom, hydroxyl group, —O—CH₂—R⁴—CH₂—OR⁶, —O—CH₂—R⁵—OR⁹ or —OR¹⁶,

R⁴ and R⁵ represent a monocyclic or polycyclic cyclic hydrocarbon group or —CR⁶R⁷—,

R⁶ and R⁷ represent alkyl group,

R⁸ to R¹⁶ each independently represent a hydrogen atom, methyl group or trimethylsilyl group, and

n represents an integer of 1 or more.

<Phthalocyanine Pigment>

An explanation is first provided of the above-mentioned phthalocyanine pigment having a structure represented by general formula (1).

A pigment in the present invention refers to a coloring material having low solubility in organic solvents such as styrene, toluene, methyl ethyl ketone, ethyl acetate, acetone, methanol and N,N-dimethylformamide (DMF), water, mixtures thereof and the like. “Low solubility” in the present invention refers to having solubility in organic solvents, water and mixtures thereof of less than 0.1% by mass.

There are no particular limitations on the monocyclic cyclic hydrocarbon group represented by R¹ in general formula (1), and examples thereof include a cyclobutylene group, cyclopentylene group, cyclohexylene group, cycloheptylene group, cyclooctylene group and the like.

There are no particular limitations on the polycyclic cyclic hydrocarbon group represented by R¹ in general formula (1), and examples thereof include a norbornanediyl group, norbornenediyl group, adamantanediyl group and the like.

There are no particular limitations on the alkyl groups represented by R² and R³ in general formula (1), and examples thereof include a methyl group, ethyl group, n-propyl group, iso-propyl group, n-butyl group, sec-butyl group, tert-butyl group, octyl group, dodecyl group and nonadecyl group.

Among these, from the viewpoint of color development property, R¹ is preferably a monocyclic or polycyclic cyclic hydrocarbon group, more preferably a polycyclic cyclic hydrocarbon group, and even more preferably a norbornanediyl group, norbornenediyl group or adamantanediyl group.

Examples of the aryl ring represented by

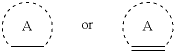

in general formula (1) include a benzene ring and naphthyl ring.

Furthermore, these rings may have substituents provided they do not affect color development property. Specific examples of substituents include alkyl groups in the manner of a methyl group, propyl group or tert-butyl group, alkoxy groups in the manner of a methoxy group, ethoxy group, propoxy group, butoxy group or hexyloxy group, a nitro group, and a halogen atom in the manner of a chlorine atom. From the viewpoint of synthesis, these substituents are not limited to being regular, but rather may also be various isomers. These isomers do not have a significant effect on color development property.

Examples of a heterocycle containing one or two nitrogen atoms represented by

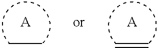

in general formula (1) include a pyridine ring, pyrazine ring, pyrrolidine ring, piperidine ring, azepane ring and azocane ring.

Among these, from the viewpoint of color development property, a substituted or unsubstituted benzene ring, pyridine ring or pyrazine ring is preferable, a substituted or unsubstituted benzene ring is more preferable, and a benzene ring having a tert-butyl group is even more preferable.

M in general formula (1) represents any metal atom selected from the group consisting of Si, Ge and Sn, and from the viewpoint of color development property, the metal atom is preferably Si.

Examples of halogen atoms represented by L₁ and L₂ in general formula (1) include chlorine atoms, bromine atoms and iodine atoms.

There are no particular limitations on monocyclic cyclic hydrocarbon groups represented by R⁴ and R⁵ in general formula (1), and examples thereof include cycloalkylene groups. Examples of these cycloalkylene groups include cyclobutylene groups, cyclopentylene groups, cyclohexylene groups, cycloheptylene groups and cyclooctylene groups.

There are no particular limitations on polycyclic cyclic hydrocarbon groups represented by R⁴ and R⁵ in general formula (1), and examples thereof include norbornanediyl groups, norbornenediyl groups and adamantanediyl groups.

There are no particular limitations on alkyl groups represented by R⁶ and R⁷ in general formula (1), and examples thereof include methyl groups, ethyl groups, n-propyl groups, iso-propyl groups, n-butyl groups, sec-butyl groups, tert-butyl groups, octyl groups, dodecyl groups and nonadecyl groups.

In addition, in the case of desiring to further increase hydrophobicity of L₁ and L₂, trimethylsilyl groups or methyl groups are used for R⁸ to R¹⁰.

In general formula (1), n represents an integer of 1 or more. In the case n is 0, function as a pigment having strong lightfastness is not adequately demonstrated as a result of having high solubility in solvents in the manner of toluene and ethanol. In contrast, although a larger value for n is preferable for use as a pigment having superior lightfastness, n is preferably from 1 to 10, and when considering lightfastness, n is more preferably from 2 to 10 since it becomes theoretically difficult to release active oxygen.

The phthalocyanine pigment having a structure represented by general formula (1) according to the present invention can be synthesized by referring to known methods described in, for example, Die Makromolekulare Chemie, 175, 714-728 (1974), Polymer Journal, 27, 11, 1079-1084 (1995), and Angew. Chem. Int. Ed., 37, 8, 1092-1094 (1998).

Although the following indicates one aspect of a method for producing the above-mentioned phthalocyanine pigment having a structure represented by general formula (1), the production method is not limited thereto.

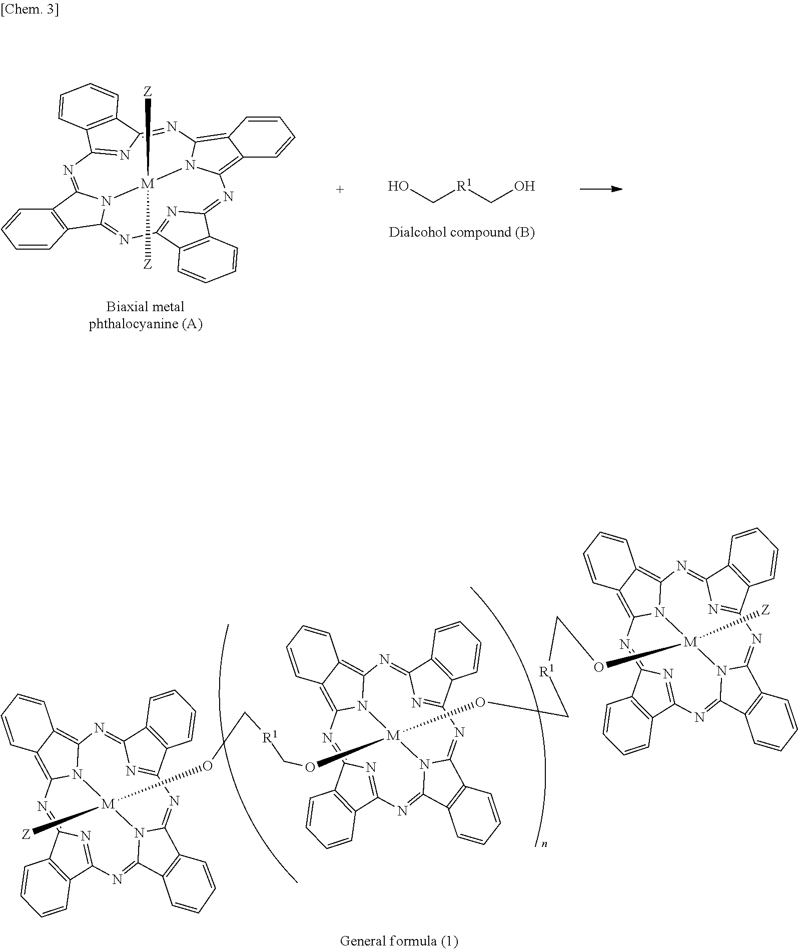

The phthalocyanine pigment of the present invention can be easily obtained by condensing a biaxial metal phthalocyanine (A) and a dialcohol compound (B).

Preferable examples of Z in the above-mentioned biaxial metal phthalocyanine (A) include halogen atoms such as a chlorine atom and hydroxyl groups.

The biaxial metal phthalocyanine (A) was synthesized with reference to, for example, the Journal of the American Chemical Society, 105, 1539-1550 (1983). Namely, synthesis was carried out by stirring a 1,3-diiminoisoindoline derivative synthesized from a phthalonitrile derivative and a metal halide compound under conditions of heating at 200° C. or higher in a high boiling point solvent.

Next, a description is provided for the condensation step of the biaxial metal phthalocyanine (A) and the dialcohol compound (B).

Although this condensation step can also be carried out in the absence of a solvent, it is preferably carried out in the presence of a solvent. There are no particular limitations on the solvent provided it does not participate in the reaction, and examples thereof include toluene, xylene, monochlorobenzene, dichlorobenzene, pyridine and quinoline.

In addition, a mixture of two or more types of solvents can also be used, and the mixing ratio when using that mixture can be set arbitrarily. The amount of the above-mentioned reaction solvent used is preferably within the range of 0.1 times to 1000 times (based on mass), and more preferably 1.0 times to 150 times (based on mass), of the biaxial metal phthalocyanine.

The reaction temperature of the condensation step is preferably within the range of −80° C. to 250° C. and more preferably within the range of —20° C. to 150° C. The reaction is normally completed within 10 hours.

In the condensation step, the reaction may be made to proceed rapidly by adding a base as necessary.

Specific examples of bases used in the condensation step include metal alkoxides in the manner of potassium tert-butoxide, sodium tert-butoxide, sodium methoxide or sodium ethoxide; organic bases in the manner of piperidine, pyridine, 2-methylpyridine, diethylamine, triethylamine, isopropylethylamine, potassium acetate or 1,8-diazabicyclo[5.4.0]undeca-7-ene (DBU); organic bases in the manner of n-butyl lithium or tert-butyl magnesium chloride; and inorganic bases in the manner of sodium borohydride, sodium metal, sodium hydride or sodium carbonate. Preferable examples include potassium tert-butoxide, sodium hydride, sodium methoxide, sodium ethoxide and piperidine, while more preferable examples include sodium hydride and piperidine because of their low cost and handling ease.

The amount of the above-mentioned base (such as sodium hydride) used is preferably 1.0 equivalent to 100 equivalents, more preferably 1.5 equivalents to 20 equivalents, and even more preferably 5.0 equivalents to 10 equivalents based on a single hydroxyl group of the dialcohol compound (B).

Preferable examples of the above-mentioned dialcohol compound (B) include 2,2-dimethyl-1,3-propanediol, 2-ethyl-2-methyl-1,3-propanediol, 2-methyl-2-propyl-1,3-propanediol, 2,2-diethyl-1,3-propanediol, 2,2-di-n-octyl-1,3-propanediol, 2,2-diisobutyl-1,3-propanediol, 5-norbornene-2,2-dimethanol, 1,4-cyclohexane dimethanol, 1,2-cyclohexane dimethanol, 5-norbornene-2,3-dimethanol and 1,3-adamantane dimethanol.

Among these, bulky cyclic compounds like 1,4-cyclohexane dimethanol, 1,2-cyclohexane dimethanol, 5-norbornene-2,3-dimethanol or 1,3-adamantane dimethanol are preferable since they have superior color development property, and color development property in the case of using that having a structure having polycyclic cyclic hydrocarbon group in the manner of 5-norbornene-2,3-dimethanol or 1,3-adamantane dimethanol is particularly preferable.

In addition, the amount of the dialcohol compound (B) used is preferably 0.1 equivalents to 10 equivalents, more preferably 0.5 equivalents to 5 equivalents, and even more preferably 0.8 equivalents to 1.5 equivalents, based on the biaxial metal phthalocyanine (A).

Following completion of the reaction, the solid is filtered and the residue is washed with a nonpolar solvent in the manner of n-hexane, n-heptane or toluene, followed by washing with a polar solvent in the manner of an alcohol and then washing with ion exchange water and the like to obtain the phthalocyanine pigment having a structure represented by general formula (1). In addition, washing can also be carried out with a Soxhlet extractor and the like using a heated solvent in the manner of dichloromethane, chloroform, toluene, xylene or N,N-dimethylformamide.

The phthalocyanine pigment having a structure represented by general formula (1) of the present invention may be used alone or two or more types may be used in combination corresponding to the application in which it is used in order to adjust color tone and the like. Moreover, it can also be used in combination with two or more types of known pigments or dyes.

Specific preferable examples of the phthalocyanine pigment of the present invention include, but are not limited to, compounds (1) to (27) indicated below.

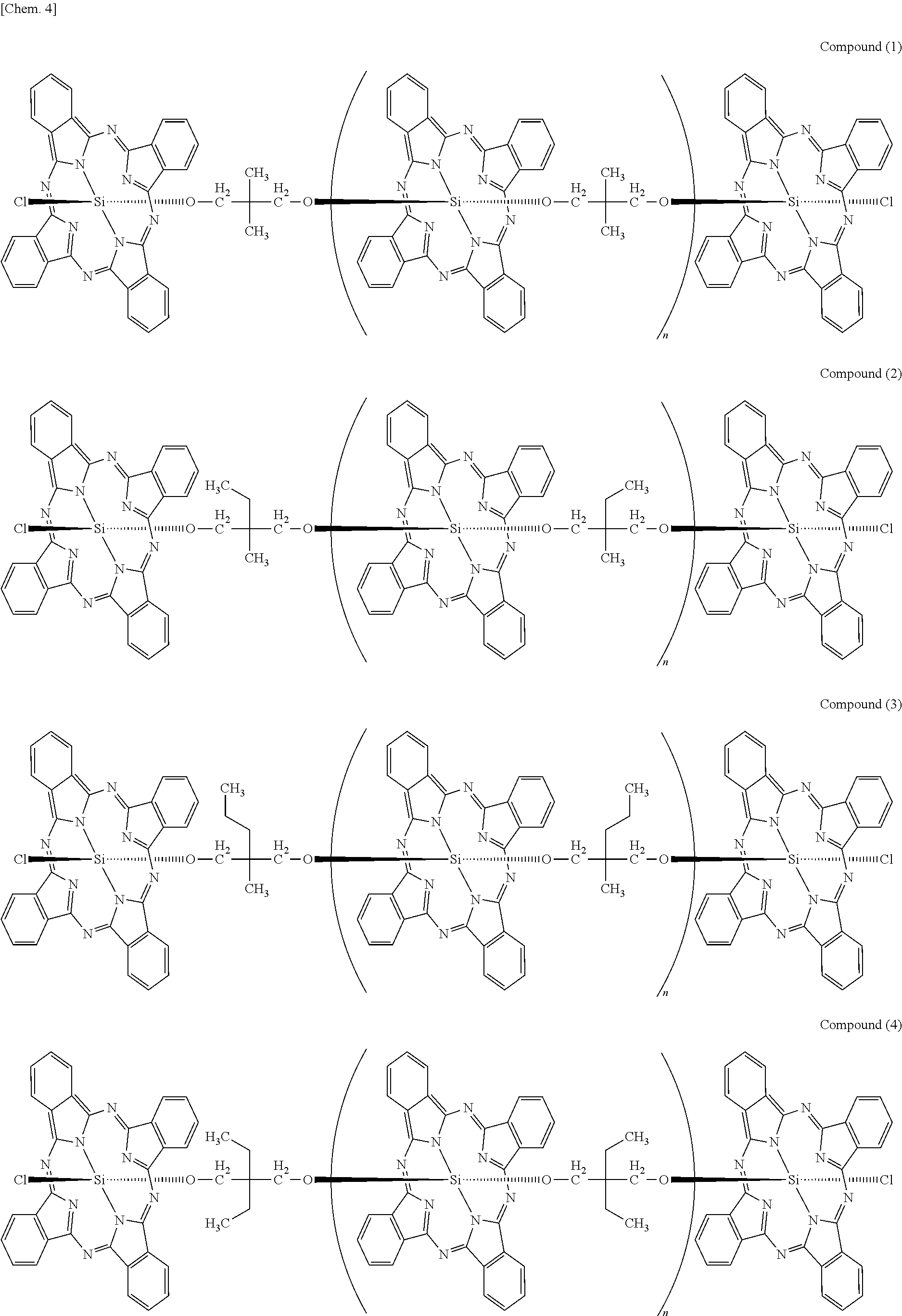

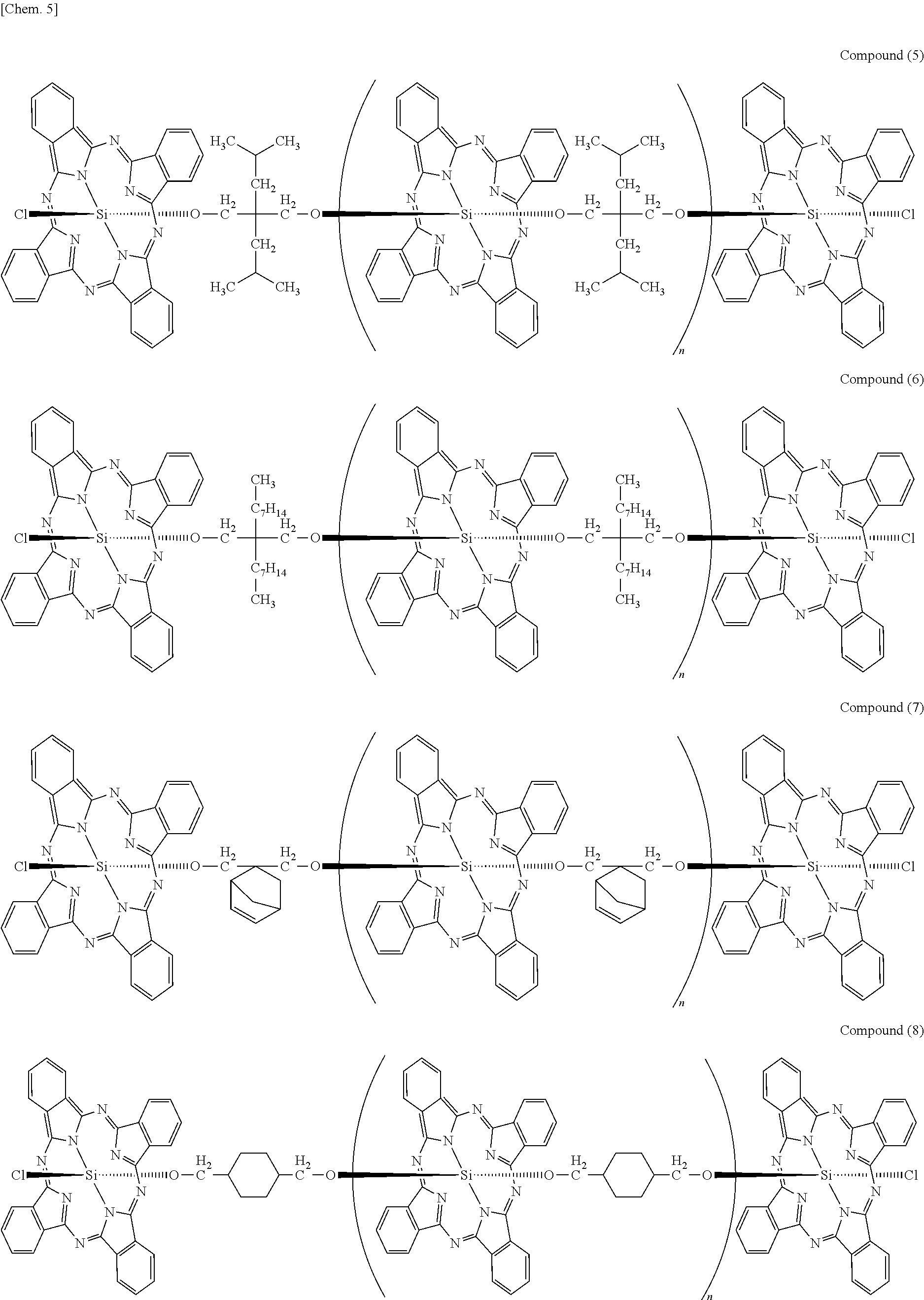

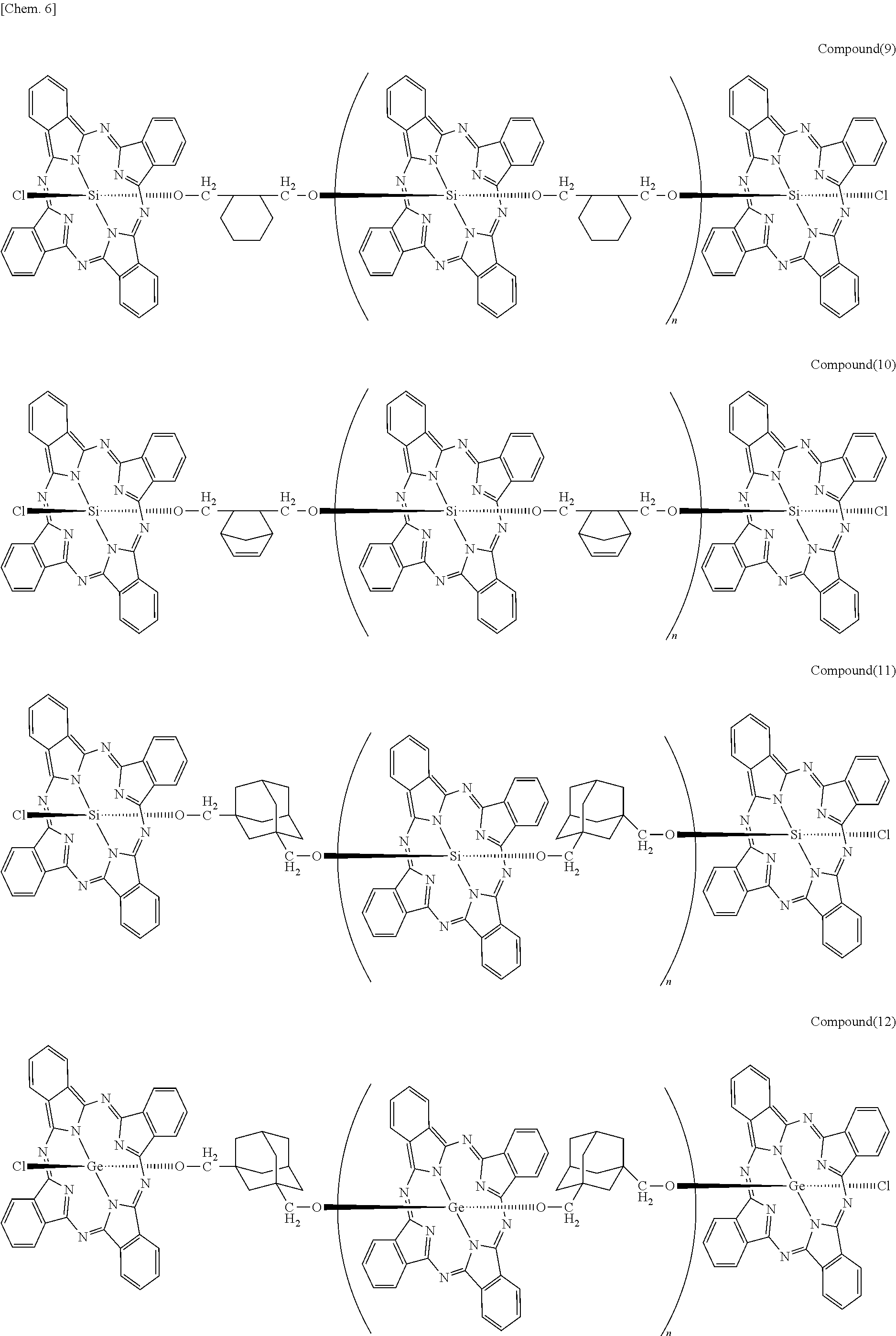

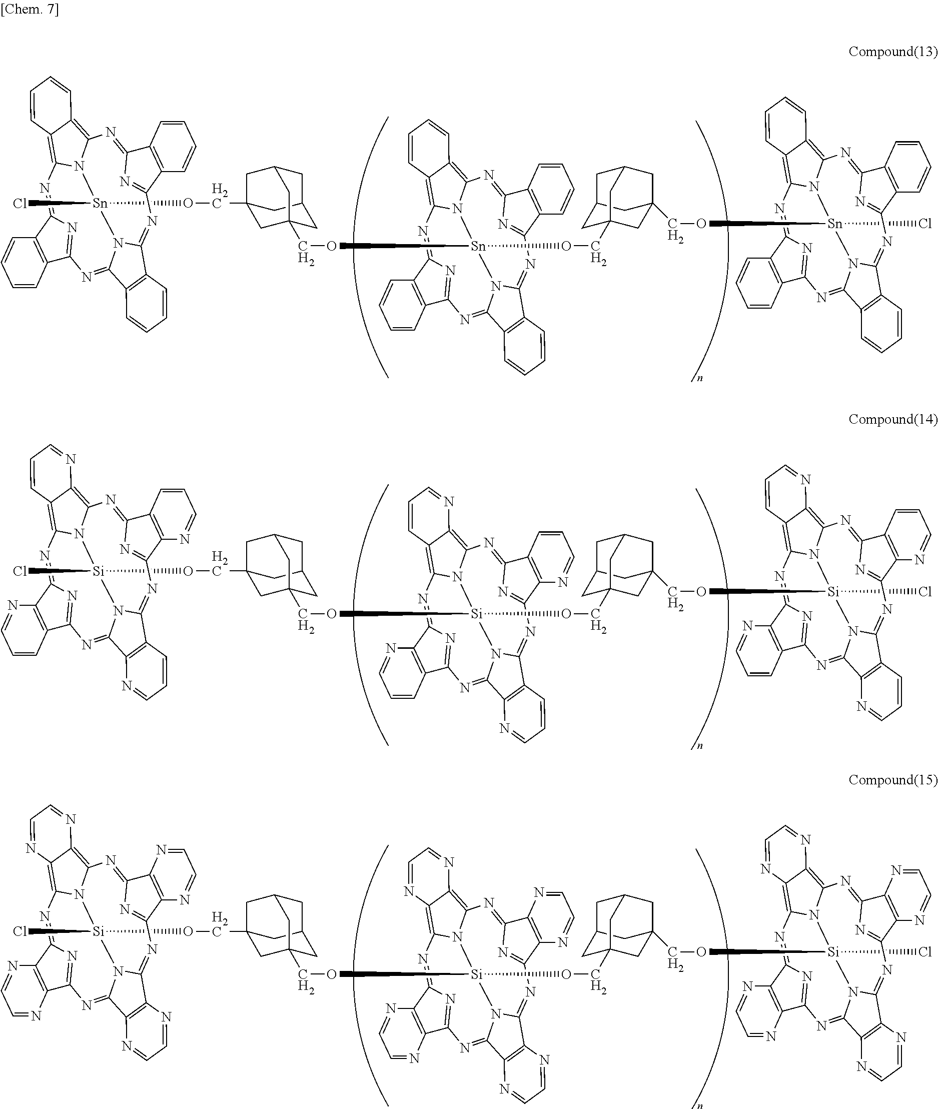

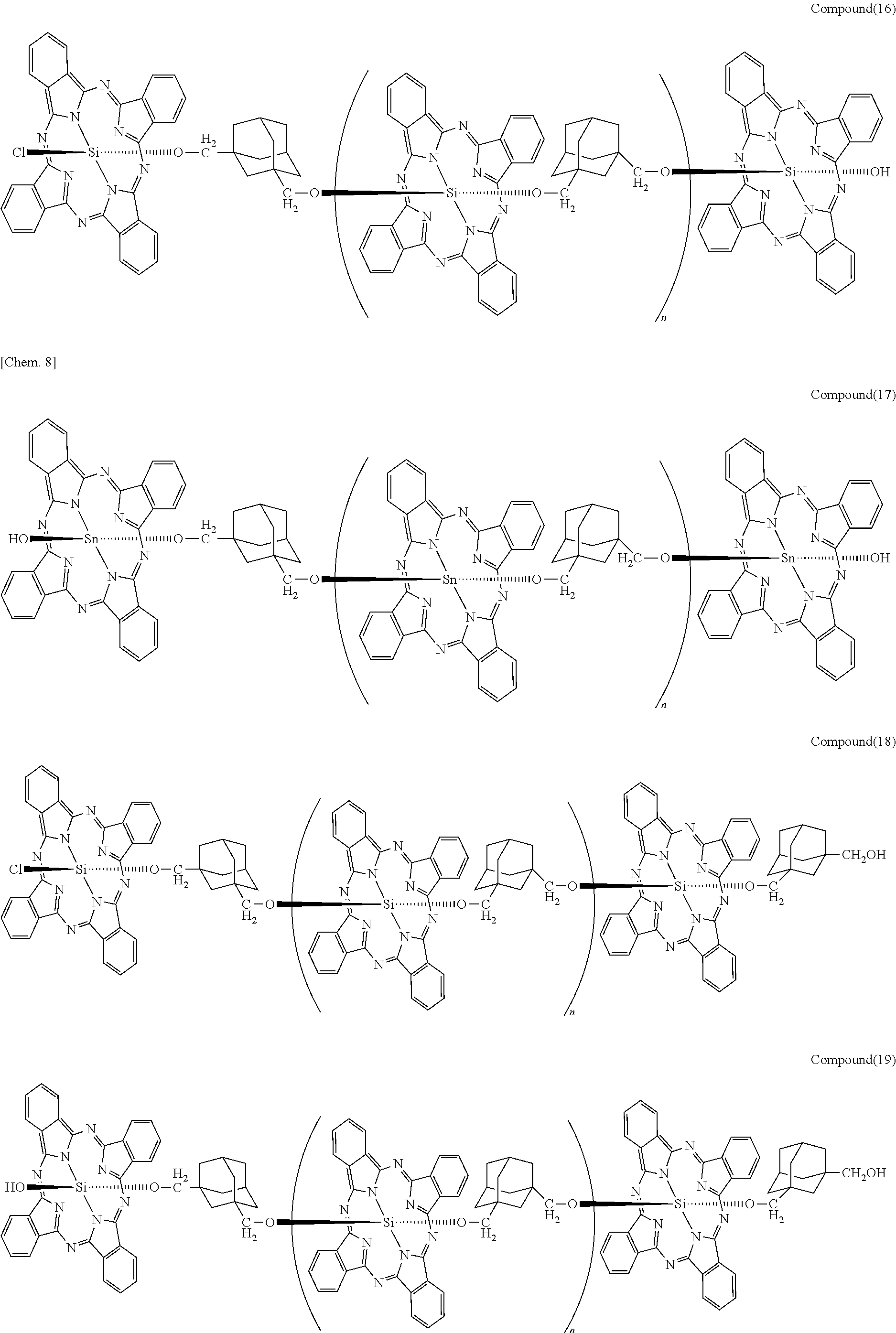

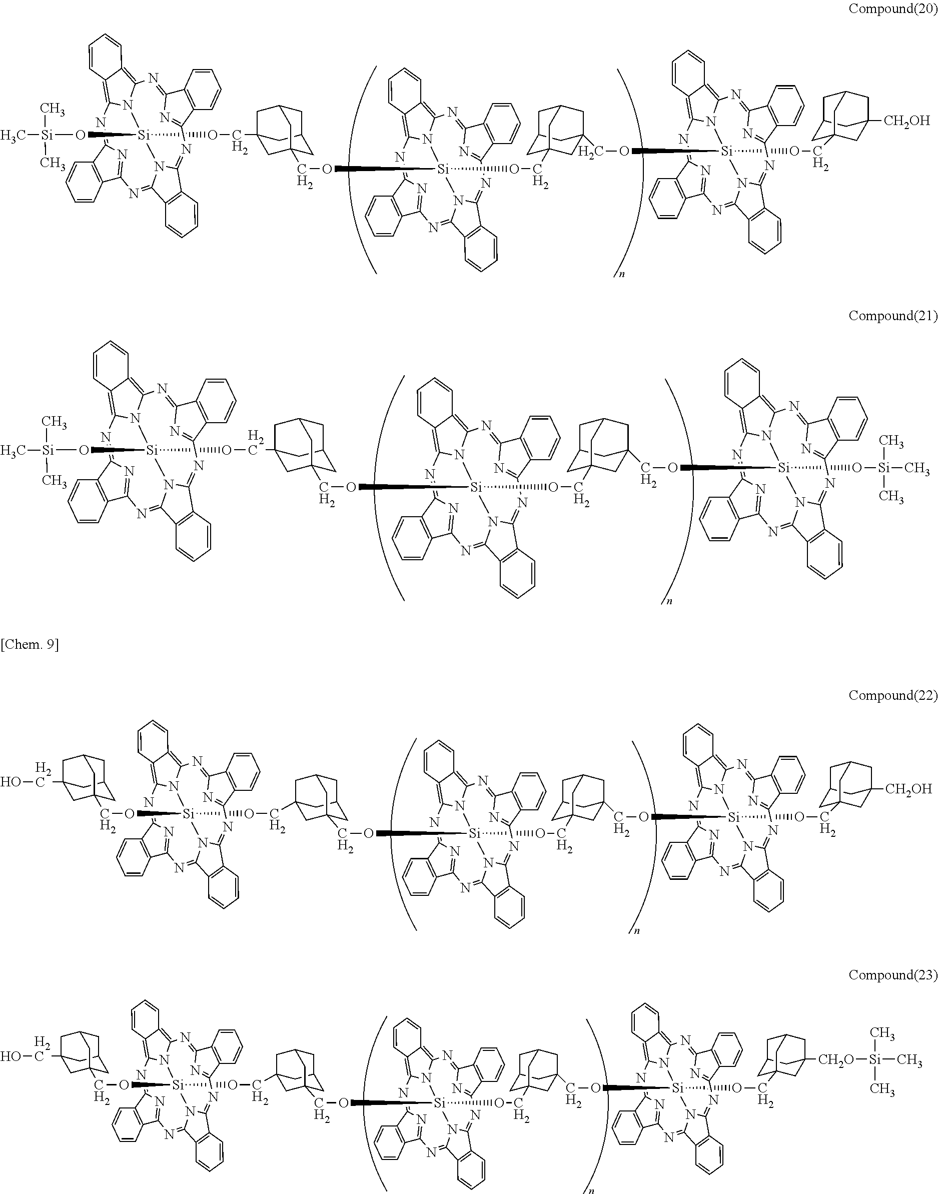

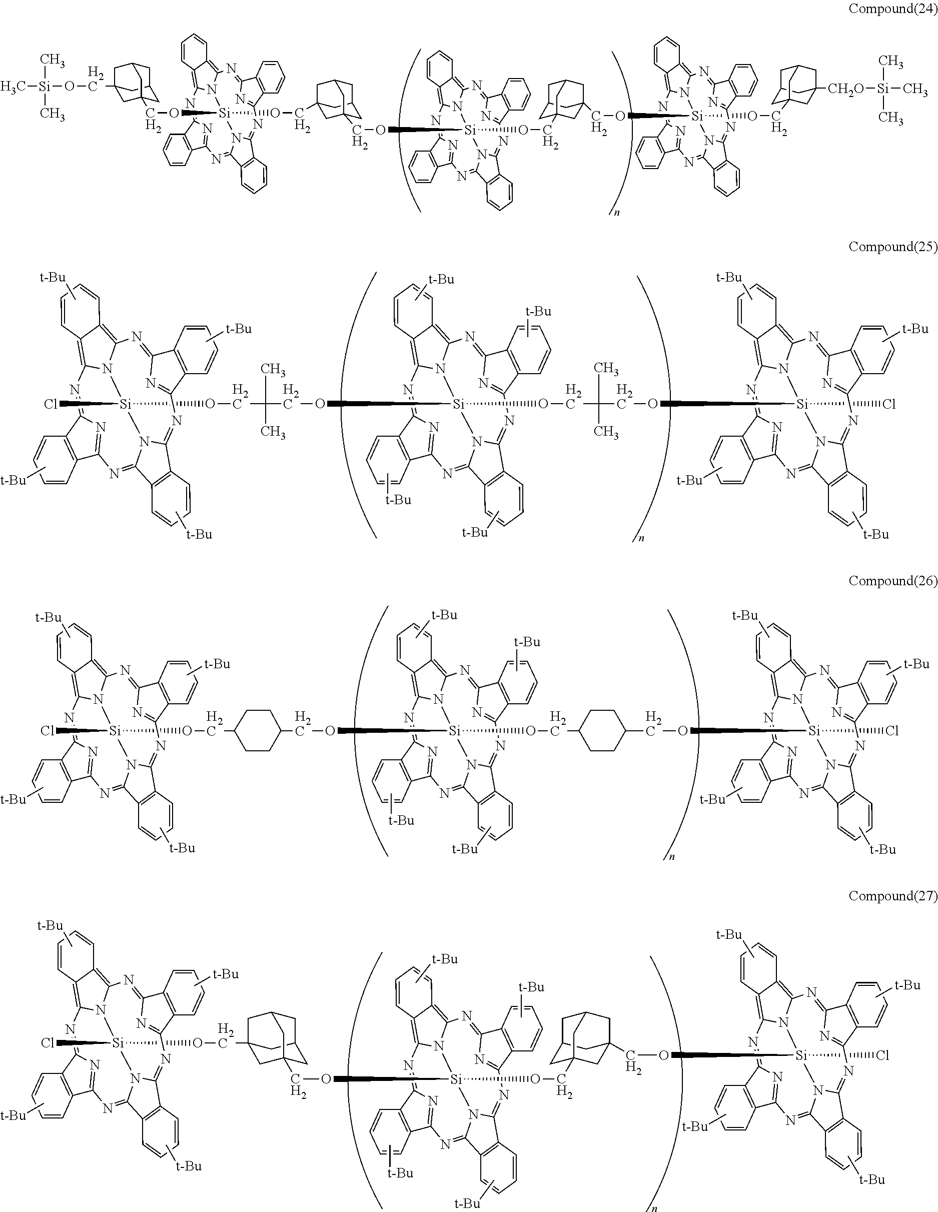

In the above-mentioned formulas, n represents the mixture of an integer of 1 to 10, and t-Bu represents a tert-butyl group.

<Pigment Dispersion>

The pigment dispersion of the present invention is characterized by containing a dispersion medium and the phthalocyanine pigment of the present invention. A dispersion medium as referred to in the present invention refers to water, an organic solvent or a mixture thereof.

The pigment dispersion of the present invention is obtained by dispersing the above-mentioned phthalocyanine pigment having a structure represented by general formula (1) in a dispersion medium. An example of a specific method thereof is indicated below. Namely, a pigment liquid dispersion is produced by adequately blending the above-mentioned phthalocyanine pigment having a structure represented by general formula (1) into a dispersion medium, in which a resin has been dissolved as necessary, by stirring and the like.

Moreover, pigment can be finely dispersed into fine particles to obtain a pigment dispersion by applying mechanical shearing force to a pigment liquid dispersion with a disperser in the manner of a ball mill, paint shaker, dissolver, attritor, sand mill, high-speed mill or high-pressure disperser.

In the present invention, the content of the phthalocyanine pigment in the pigment dispersion is preferably 1.0 part by mass to 100 parts by mass, more preferably 2.0 parts by mass to 80 parts by mass, and particularly preferably 3.0 parts by mass to 70 parts by mass based on 100 parts by mass of the dispersion medium. If the content of the phthalocyanine pigment is within the above-mentioned ranges, increases in viscosity and decreases in pigment dispersibility can be prevented, and favorable tinting strength can be demonstrated.

In the present invention, the pigment dispersion can be dispersed in water using an emulsifier. Examples of emulsifiers include cationic surfactants, anionic surfactants and nonionic surfactants. Examples of cationic surfactants include dodecyl ammonium chloride, dodecyl ammonium bromide, dodecyl trimethyl ammonium bromide, dodecyl pyridinium chloride, dodecyl pyridinium bromide and hexadecyl trimethyl ammonium bromide.

Examples of anionic surfactants include fatty acid soaps such as sodium stearate or sodium dodecanoate, sodium dodecyl sulfate, sodium dodecyl benzene sulfate and sodium lauryl sulfate.

Examples of nonionic surfactants include polyoxyethylene dodecyl ether, polyoxyethylene hexadecyl ether, polyoxyethylene nonylphenyl ether, polyoxyethylene lauryl ether, polyoxyethylene sorbitanmonooleate ether and monodecanoyl sucrose.

The following lists examples of organic solvents able to be used as dispersion media:

alcohols in the manner of methyl alcohol, ethyl alcohol, denatured ethyl alcohol, isopropyl alcohol, n-butyl alcohol, isobutyl alcohol, tert-butyl alcohol, sec-butyl alcohol, tert-amyl alcohol, 3-pentanol, octyl alcohol, benzyl alcohol and cyclohexanol; glycols in the manner of methyl cellosolve, ethyl cellosolve, diethylene glycol and diethylene glycol monobutyl ether; ketones in the manner of acetone, methyl ethyl ketone and methyl isobutyl ketone; esters in the manner of ethyl acetate, butyl acetate, ethyl propionate and cellosolve acetate; hydrocarbon-based solvents in the manner of hexane, octane, petroleum ether, cyclohexane, benzene, toluene and xylene; halogenated hydrocarbon-based solvents in the manner of carbon tetrachloride, trichloroethylene and tetrabromoethane; ethers in the manner of diethyl ether, dimethyl glycol, trioxane and tetrahydrofuran; acetals in the manner of methylal and diethyl acetal; organic acids in the manner of formic acid, acetic acid and propionic acid; and, sulfur/nitrogen-containing organic compounds in the manner of nitrobenzene, dimethylamine, monoethanolamine, pyridine, dimethylsulfoxide and dimethylformamide.

In addition, a polymerizable monomer can also be used for the organic solvent. The polymerizable monomer is an addition polymerizable or condensation polymerizable monomer, and is preferably an addition polymerizable monomer. Specific examples thereof include:

styrene-based monomers in the manner of styrene, o-methylstyrene, m-methylstyrene, p-methylstyrene, o-ethylstyrene, m-ethylstyrene and p-ethylstyrene; acrylate-based monomers in the manner of methyl acrylate, ethyl acrylate, propyl acrylate, butyl acrylate, octyl acrylate, dodecyl acrylate, stearyl acrylate, behenyl acrylate, 2-ethylhexyl acrylate, dimethylaminoethyl acrylate, diethylaminoethyl acrylate, acrylonitrile and acrylic acid amide; methacrylate-based monomers in the manner of methyl methacrylate, ethyl methacrylate, propyl methacrylate, butyl methacrylate, octyl methacrylate, dodecyl methacrylate, stearyl methacrylate, behenyl methacrylate, 2-ethylhexyl methacrylate, dimethylaminoethyl methacrylate, diethylaminoethyl methacrylate, methacrylonitrile and methacrylic acid amide; olefin-based monomers in the manner of ethylene, propylene, butylene, butadiene, isoprene, isobutylene and cyclohexene; vinyl halides in the manner of vinyl chloride, vinylidene chloride, vinyl bromide and vinyl iodide; vinyl esters in the manner of vinyl acetate, vinyl propionate and vinyl benzoate; vinyl ethers in the manner of vinyl methyl ether, vinyl ethyl ether and vinyl isobutyl ether; and, vinyl ketone compounds in the manner of vinyl methyl ketone, vinyl hexyl ketone and methyl isopropenyl ketone. These can be used alone or two or more types can be used in combination corresponding to the application in which they are used.

In the case of producing a polymerized toner using the pigment dispersion of the present invention, styrene or a styrene-based monomer among the above-mentioned polymerizable monomers is used preferably either alone or by mixing with other polymerizable monomers. Styrene is particularly preferable based on its handling ease.

A resin may also be further added to the above-mentioned pigment dispersion. Specific examples thereof include:

polystyrene resins, styrene copolymers, polyacrylic acid resins, polymethacrylic acid resins, polyacrylic acid ester resins, polymethacrylic acid ester resins, acrylic acid-based copolymers, methacrylic acid-based copolymers, polyester resins, polyvinyl ether resins, polyvinyl methyl ether resins, polyvinyl alcohol resins, polyvinyl butyral resins, polyurethane resins and polypeptide resins.

These resins can be used alone or two or more types can be used by mixing.

In the pigment dispersion of the present invention, other colorants can be used in combination provided they do not inhibit dispersibility. Examples of colorants that can be used in combination include: C.I. Solvent Blue 14, 24, 25, 26, 34, 37, 38, 39, 42, 43, 44, 45, 48, 52, 53, 55, 59, 67 and 70; and, C.I. Solvent Red 8, 27, 35, 36, 37, 38, 39, 40, 49, 58, 60, 65, 69, 81, 83:1, 86, 89, 91, 92, 97, 99, 100, 109, 118, 119, 122, 127 and 218.

<Ink>

The ink of the present invention is characterized by containing the pigment dispersion of the present invention.

The phthalocyanine pigment having a structure represented by general formula (1) has superior color development property and lightfastness, and is preferable for use in ink colorant applications.

The ink of the present invention at least contains the above-mentioned dispersion medium and the phthalocyanine pigment having a structure represented by general formula (1).

In the ink of the present invention, constituent components other than those described above are respectively determined corresponding to the application in which the ink of the present invention is used, and additives can be added within a range that does not impair properties in the various applications in which the ink is used.

The ink of the present invention can be preferably used as inkjet ink as well as printing ink, paint and writing instrument ink. In particular, the ink of the present invention can be particularly preferably used as an ink for color filter resist applications to be subsequently described.

The ink of the present invention can be produced, for example, in the manner described below.

A pigment liquid dispersion is produced by adding the above-mentioned phthalocyanine pigment having a structure represented by general formula (1) to a dispersion medium containing another colorant, emulsifier or resin and the like as necessary, followed by adequately blending into the medium. Moreover, the pigment can be finely dispersed into fine particles to obtain an ink by applying mechanical shearing force to a pigment liquid dispersion with a disperser in the manner of a ball mill, paint shaker, dissolver, attritor, sand mill, high-speed mill or high-pressure disperser. In the present invention, the above-mentioned “dispersion medium” refers to water, an organic solvent or a mixture thereof.

In the case of using an organic solvent for the dispersion medium of the ink of the present invention, the type of organic solvent is determined corresponding to the target application of the colorant, and although there are no particular limitations thereon, examples thereof include alcohols in the manner of methanol, ethanol, denatured ethanol, isopropanol, n-butanol, isobutanol, tert-butanol, sec-butanol, 2-methyl-2-butanol, 3-pentanol, octanol, benzyl alcohol and cyclohexanol; glycols in the manner of methyl cellosolve, ethyl cellosolve, diethylene glycol and diethylene glycol monobutyl ether; ketones in the manner of acetone, methyl ethyl ketone and methyl isobutyl ketone; esters in the manner of ethyl acetate, butyl acetate, ethyl propionate and cellosolve acetate; aliphatic hydrocarbons in the manner of hexane, octane, petroleum ether and cyclohexane; aromatic hydrocarbons in the manner of benzene, toluene and xylene; halogenated hydrocarbons in the manner of carbon tetrachloride, trichloroethylene and tetrabromoethane; ethers in the manner of diethyl ether, dimethyl glycol, trioxane and tetrahydrofuran; acetals in the manner of methylal and diethyl acetal; organic acids in the manner of formic acid, acetic acid and propionic acid; and, sulfur/nitrogen-containing organic compounds in the manner of nitrobenzene, dimethylamine, monoethanolamine, pyridine, dimethylsulfoxide and dimethylformamide.

In addition, a polymerizable monomer can also be used as an organic solvent able to be used in the ink of the present invention. The polymerizable monomer is an addition polymerizable or condensation polymerizable monomer, and is preferably an addition polymerizable monomer. Examples of such polymerizable monomers include:

styrene-based monomers in the manner of styrene, α-methylstyrene, α-ethylstyrene, o-methylstyrene, m-methylstyrene, p-methylstyrene, o-ethylstyrene, m-ethylstyrene and p-ethylstyrene; acrylate-based monomers in the manner of methyl acrylate, ethyl acrylate, propyl acrylate, butyl acrylate, octyl acrylate, dodecyl acrylate, stearyl acrylate, behenyl acrylate, 2-ethylhexyl acrylate, dimethylaminoethyl acrylate, diethylaminoethyl acrylate, acrylonitrile and acrylic acid amide; methacrylate-based monomers in the manner of methyl methacrylate, ethyl methacrylate, propyl methacrylate, butyl methacrylate, octyl methacrylate, dodecyl methacrylate, stearyl methacrylate, behenyl methacrylate, 2-ethylhexyl methacrylate, dimethylaminoethyl methacrylate, diethylaminoethyl methacrylate, methacrylonitrile and methacrylic acid amide; olefin-based monomers in the manner of ethylene, propylene, butylene, butadiene, isoprene, isobutylene and cyclohexene; vinyl halide-based monomers in the manner of vinyl chloride, vinylidene chloride, vinyl bromide and vinyl iodide; vinyl ester-based monomers in the manner of vinyl acetate, vinyl propionate and vinyl benzoate; vinyl ether-based monomers in the manner of vinyl methyl ether, vinyl ethyl ether and vinyl isobutyl ether; and, vinyl ketone-based monomers in the manner of vinyl methyl ketone, vinyl hexyl ketone and methyl isopropenyl ketone. These can be used alone or two or more types can be used in combination as necessary.

Although at least the phthalocyanine pigment having a structure represented by general formula (1) is used as colorant that composes the ink of the present invention, other colorants can also be used in combination as necessary provided they do not impair the solubility or dispersibility of the phthalocyanine pigment in the dispersion medium.

Although examples of other colorants that can be used in combination include C.I. Solvent Blue 14, 24, 25, 26, 34, 37, 38, 39, 42, 43, 44, 45, 48, 52, 53, 55, 59, 67 and 70; and, C.I. Solvent Red 8, 27, 35, 36, 37, 38, 39, 40, 49, 58, 60, 65, 69, 81, 83:1, 86, 89, 91, 92, 97, 99, 100, 109, 118, 119, 122, 127 and 218, colorants able to be used in combination in the present invention are not limited thereto.

In the ink of the present invention, the content of the phthalocyanine pigment of the present invention is preferably 1.0 part by mass to 30 parts by mass, more preferably 2.0 parts by mass to 20 parts by mass, and even more preferably 3.0 parts by mass to 15 parts by mass based on 100 parts by mass of the dispersion medium. If the content of the phthalocyanine pigment is within the above-mentioned ranges, adequate tinting strength is obtained while also demonstrating favorable colorant dispersibility.

In the case of using water for the dispersion medium of the ink of the present invention, an emulsifier can be added in order to obtain favorable dispersion stability of the phthalocyanine pigment of the present invention and colorant used in combination therewith, as necessary. There are no particular limitations on emulsifiers able to be added, and examples thereof include cationic surfactants, anionic surfactants and nonionic surfactants.

Examples of cationic surfactants in the above-mentioned emulsifier include dodecyl ammonium chloride, dodecyl ammonium bromide, dodecyl trimethyl ammonium bromide, dodecyl pyridinium chloride, dodecyl pyridiniumbromide and hexadecyl trimethyl ammonium bromide.

Examples of anionic surfactants in the above-mentioned emulsifier include fatty acid soaps in the manner of sodium stearate and sodium dodecanoate, sodium dodecyl sulfate, sodium dodecyl benzene sulfate and sodium lauryl sulfate.

Examples of nonionic surfactants in the above-mentioned emulsifier include polyoxyethylene dodecyl ether, polyoxyethylene hexadecyl ether, polyoxyethylene nonylphenyl ether, polyoxyethylene lauryl ether, polyoxyethylene sorbitan monooleate ether and monodecanoyl sucrose.

A resin can also be further added to the ink of the present invention. The type of resin able to be added to the ink of the present invention is determined corresponding to the target application, and although there are no particular limitations thereon, examples include polystyrene resins, styrene copolymers, polyacrylic acid resins, polymethacrylic acid resins, polyacrylate resins, polymethacrylate resins, acrylic acid-based copolymers, methacrylic acid-based copolymers, polyester resins, polyvinyl ether resins, polyvinyl methyl ether resins, polyvinyl alcohol resins, polyvinyl butyral resins, polyurethane resins and polypeptide resins. These resins can be used alone or two or more types can be used in combination as necessary.

As has been described above, the ink of the present invention is able to provide an ink having superior color development property and lightfastness as a result of being composed by containing the phthalocyanine pigment of the present invention.

<Color Filter Resist Composition>

Since the phthalocyanine pigment having a structure represented by general formula (1) of the present invention has superior color development property, it can be preferably used in a color filter resist composition.

The color filter resist composition of the present invention contains at least one of a binder resin and polymerizable monomer, and the phthalocyanine pigment having a structure represented by general formula (1). The color filter resist composition of the present invention can be produced, for example, in the manner indicated below.

Namely, at least one of a binder resin and polymerizable monomer, the phthalocyanine pigment having a structure represented by general formula (1), and as necessary, a polymerization initiator, photoacid generator and the like, are gradually added to a dispersion medium while stirring, followed by adequately blending into the dispersion medium. Moreover, the color filter resist composition of the present invention can be obtained by stably dissolving or finely dispersing by applying mechanical shearing force with a disperser.

Binder resin able to be used in the color filter resist composition of the present invention is that which allows one of a light irradiated portion or light shielding portion to be able to be dissolved by an organic solvent, aqueous alkaline solution, water or commercially available developer and the like in an exposure step during pixel formation. In particular, from the viewpoints of workability, waste treatment and the like, the binder resin preferably has a composition that enables development with water or an aqueous alkaline solution.

A typical known example of the above-mentioned binder resin is that which is obtained by copolymerizing a hydrophilic polymerizable monomer and a lipophilic polymerizable monomer at a suitable mixing ratio using a known technique. Examples of hydrophilic polymerizable monomers include acrylic acid, methacrylic acid, N-(2-hydroxyethyl)acrylamide, N-vinylpyrrolidone and polymerizable monomers having an ammonium salt. In addition, examples of lipophilic polymerizable monomers include acrylic acid esters, methacrylic acid esters, vinyl acetate, styrene and N-vinylcarbazole.

These binder resins can be used as a negative resist, namely a type of resist in which only a light shielding portion is removed by development as a result of the solubility in developer being lowered due to exposure to light. In addition, in order to use as a negative resist, the binder resin may be used in combination with a radical polymerizable monomer having an ethylenic unsaturated group, cationic polymerizable monomer having an oxirane ring or oxetane ring, radical generator, acid generator or base generator.

In addition, a combination of a binder resin having a group that is cleaved by light or acid and an acid generator that generates acid when exposed to light can also be used. This type of binder resin can be used as a positive resist, namely a type of resist in which only an exposed portion is removed by development as a result of the solubility in developer being improved due to exposure to light. An example of a binder resin having a group that is cleaved by light is a resin having a quinone diazide group that forms a carboxyl group. In addition, examples of binder resins having a group that is cleaved by acid include tert-butyl carbonic acid esters and tetrahydropyranyl ethers of polyhydroxystyrene.

In the case the color filter resist composition of the present invention is a negative resist composition as described above, the polymerizable monomer that is addition-polymerized by exposure to light can be composed by comprising a photopolymerizable monomer having one or more ethylenic unsaturated double bonds. Examples of the photopolymerizable monomer include compounds having at least one addition-polymerizable ethylenic unsaturated group in a molecule thereof, and a boiling point at normal pressure of 100° C. or higher.

Examples thereof include monofunctional acrylates such as polyethylene glycol monoacrylate, polyethylene glycol monomethacrylate, polypropylene glycol monoacrylate, polypropylene glycol monomethacrylate, phenoxyethyl acrylate or phenoxyethyl methacrylate; polyfunctional acrylates and methacrylates in the manner of polyethylene glycol diacrylate, polyethylene glycol dimethacrylate, polypropylene glycol diacrylate, polypropylene glycol dimethacrylate, trimethylolethane triacrylate, trimethylolethane trimethacrylate, trimethylolpropane triacrylate, trimethylolpropane trimethacrylate, trimethylolpropane diacrylate, trimethylolpropane dimethacrylate, neopentylglycol diacrylate, neopentylglycol dimethacrylate, pentaerythritol tetraacrylate, pentaerythritol tetramethacrylate, pentaerythritol triacrylate, pentaerythritol trimethacrylate, dipentaerythritol hexaacrylate, dipentaerythritol hexamethacrylate, dipentaerythritol pentaacrylate, dipentaerythritol pentamethacrylate, hexanediol diacrylate, hexanediol dimethacrylate, trimethylolpropane tri(acryloyloxypropyl)ether, tri(acryloyloxyethyl)isocyanurate, tri(acryloyloxyethyl)cyanurate, glycerin triacrylate and glycerin trimethacrylate; and, polyfunctional acrylates and polyfunctional methacrylates such as those obtained by adding ethylene oxide or propylene oxide to a polyfunctional alcohol in the manner of trimethylolpropane or glycerin followed by acrylation or methacrylation.

Moreover, other examples include urethane acrylates, polyester acrylates, and reaction products of epoxy resin and acrylic acid or methacrylic acid in the form of polyfunctional epoxy acrylates and epoxy methacrylates.

Among these, trimethylolpropane triacrylate, trimethylolpropane trimethacrylate, pentaerythritol tetraacrylate, pentaerythritol tetramethacrylate, dipentaerythritol hexaacrylate, dipentaerythritol hexamethacrylate, dipentaerythritol pentaacrylate and dipentaerythritol pentamethacrylate can be used preferably.

The above-mentioned photopolymerizable monomers maybe used alone or two or more types may be used in combination as necessary.

The content of the above-mentioned photopolymerizable monomer is preferably 5% by mass to 50% by mass and more preferably 10% by mass to 40% by mass of the mass (total solid content) of the resist composition of the present invention. If the above-mentioned content is less than 5% by mass, sensitivity to light exposure and pixel strength may decrease, while if the content exceeds 50% by mass, adhesiveness of the resist composition tends to be excessive.

In the case the color filter resist composition of the present invention is a negative resist composition as previously described, the color filter resist composition may also contain a photopolymerization initiator. Examples of the photopolymerization initiator include bicynal polyketoaldonyl compounds, a-carbonyl compounds, acyoin ethers, multi-branched quinone compounds, combinations of triallyl imidazole dimers and p-aminophenyl ketones and trioxadiazole compounds, and is preferably 2-benzyl-2-dimethylamino-1-(4-morpholinophenyl)butanone (trade name: Irgacure 369, BASF Corp.). Furthermore, the above-mentioned photopolymerization initiator is not required in the case of using an electron beam during pixel formation with the above-mentioned resist composition.

In the case the color filter resist composition of the present invention is a positive resist composition as described above, a photoacid generator can also be added as necessary. Examples of the photoacid generator include, but are not limited to, conventionally known photoacid generators consisting of salts of anions and onium ions in the manner of sulfonium, iodinium, selenonium, ammonium and phosphonium ions.

Examples of the above-mentioned sulfonium ions include triphenyl sulfonium, tri-p-tolylsulfonium, tri-o-tolylsulfonium, tris(4-methoxyphenyl)sulfonium, 1-naphthyldiphenyl sulfonium, diphenyl phenacyl sulfonium, phenyl methylbenzyl sulfonium, 4-hydroxyphenyl methylbenzyl sulfonium, dimethyl phenacyl sulfonium and phenacyl tetrahydrothiophenium ions.

Examples of the above-mentioned iodinium ions include diphenyl iodinium, di-p-tolyl iodinium, bis(4-dodecylphenyl)iodinium, bis(4-methoxyphenyl)iodinium and (4-octyloxyphenyl)phenyl iodinium ions.

Examples of the above-mentioned selenonium ions include triaryl selenonium(triphenyl selenonium, tri-p-tolyl selenonium, tri-o-tolyl selenonium, tris(4-methoxyphenyl)selenonium, 1-naphthyl diphenyl selenonium, tris(4-fluorophenyl)selenonium, tri-1-naphthyl selenonium and tri-2-naphthyl selenonium)ions.

Examples of the above-mentioned ammonium ions include tetramethyl ammonium, ethyl trimethyl ammonium, diethyl dimethyl ammonium, triethyl methyl ammonium, tetraethyl ammonium, trimethyl-n-propyl ammonium, trimethyl isopropyl ammonium, trimethyl-n-butyl ammonium and trimethyl isobutyl ammonium ions.

Examples of the above-mentioned phosphonium ions include tetraphenyl phosphonium, tetra-p-tolyl phosphonium, tetrakis(2-methoxyphenyl)phosphonium, triphenyl benzyl phosphonium, triphenyl phenacyl phosphonium, triphenyl methyl phosphonium, triethyl benzyl phosphonium and tetraethyl phosphonium ions.

Examples of the above-mentioned anions include, but are not limited to, perhalogenic acid ions in the manner of ClO₄⁻ and BrO₄⁻, halogenated sulfonate ions in the manner of FSO₃⁻ and ClSO₃⁻, sulfate ions in the manner of CH₃SO₄⁻, CF₃SO₄⁻ and HSO₄⁻, carbonate ions in the manner of HCO₃⁻ and CH₃CO₃⁻, aluminate ions in the manner of AlCl₄⁻ and AlF₄⁻, hexafluorobismuthate ions, carboxylate ions in the manner of CH₃COO⁻, CF₃COO⁻, C₆H₅COO⁻, CH₃C₆H₄COO⁻, C₆F₅COO⁻ and CF₃C₆H₄COO⁻, aryl borate ions in the manner of B(C₆H₅)₄⁻ and CH₃CH₂CH₂CH₂B(C₆H₅)₃⁻, thiocyanate ions and nitrate ions.

Examples of dispersion media for dissolving or dispersing the color filter resist composition of the present invention include water, organic solvent and mixtures thereof.

Examples of organic solvents include cyclohexanone, ethyl cellosolve acetate, butyl cellosolve acetate, 1-methoxy-2-propyl acetate, diethylene glycol dimethyl ether, ethyl benzene, 1,2,4-trichlorobenzene, ethylene glycol diethyl ether, xylene, ethyl cellosolve, methyl-n-amyl ketone, propylene glycol monomethyl ether, toluene, methyl ethyl ketone, ethyl acetate, methanol, ethanol, isopropanol, butanol, methyl isobutyl ketone and petroleum-based solvents. These solvents can be used alone or two or more types can be used in combination. In addition, the dispersion medium used in the color filter resist composition of the present invention may be the same as or different from the above-mentioned dispersion media provided it does not impair the dispersibility of the above-mentioned phthalocyanine pigment having a structure represented by general formula (1).

In a color filter in which two or more types of pixels having different spectral characteristics are arranged mutually adjacent, the color filter resist composition of the present invention is preferably used for pixels that compose at least one color among the plurality of pixel colors (e.g., red, green and blue). As a result, a filter can be obtained in which elongation of chroma and lightness is favorable and which has favorable color tone.

In addition, the color filter resist composition can also be further used in combination with other dyes in color mixing applications in order to obtain desired spectral characteristics. There are no particular limitations on dyes able to be used in combination with the color filter resist composition, and examples include C.I. Solvent Blue 14, 24, 25, 26, 34, 37, 38, 39, 42, 43, 44, 45, 48, 52, 53, 55, 59, 67 and 70; and, C.I. Solvent Red 8, 27, 35, 36, 37, 38, 39, 40, 49, 58, 60, 65, 69, 81, 83:1, 86, 89, 91, 92, 97, 99, 100, 109, 118, 119, 122, 127 and 218.

In the color filter resist composition of the present invention, the content of the phthalocyanine pigment of the present invention is preferably 1.0% by mass to 100.0% by mass, more preferably 3.0% by mass to 70.0% by mass, and even more preferably 5.0% by mass to 50.0% by mass based on 100.0% by mass of the mass (total solid content) of the color filter resist composition of the present invention.

In addition to the previously described additives, for example, an ultraviolet absorber and/or a silane coupling agent for the purpose of improving adhesiveness with a glass substrate during filter production, may also be added to the color filter resist composition of the present invention.

Although there are no particular limitations on the above-mentioned disperser, a media disperser in the manner of a rotary shear homogenizer, ball mill, sand mill or attritor, or a high-pressure counter collision type disperser, can be used preferably.

As has been described above, as a result of being composed by containing the phthalocyanine pigment of the present invention, the color filter resist composition of the present invention is able to provide a color filter resist composition having superior color development property and lightfastness.

### EXAMPLES

Although the following provides a more detailed explanation of the present invention by indicating examples and comparative examples, the present invention is not limited to these examples. Furthermore, the terms “parts” and “%” used in the explanation are based on mass unless specifically indicated otherwise.

### Synthesis of Dichlorosilyl Phthalocyanine

Silane tetrachloride (1.8 parts) was dropped into a liquid dispersion of 1,3-diiminoisoindoline (1.0 part) in quinoline (10 parts) in a nitrogen atmosphere while being careful of generation of heat. Following completion of dropping, the temperature was raised to 230° C. followed by stirring for 5 hours. Following completion of the reaction, the reaction mixture was cooled to room temperature and the resulting solid was filtered under reduced pressure. The resulting solid was then dispersed in N,N-dimethylformamide (DMF) followed by raising the temperature to 80° C. Filtering is performed while still hot to obtain a biaxial phthalocyanine in the form of dichlorosilyl phthalocyanine (yield: 70%).

### Production Example 1

### Production of Compound (1)

Sodium hydride (0.5 parts) was gradually added to a toluene (10 parts) solution of neopentyl glycol (0.3 parts) in a nitrogen atmosphere. Next, after gradually adding the above-mentioned dichlorosilyl phthalocyanine (1.0 part), the mixture was refluxed while heating for 5 hours. Following completion of the reaction, the mixture was diluted with n-hexane and the precipitated solid was filtered. The resulting solid was washed with ethanol and ion exchange water to obtain the target Compound (1) (yield: 92%).

The resulting Compound (1) was placed in a filter paper thimble and subjected to Soxhlet extraction to obtain a compound in which the number of repeating units n of the above-mentioned Compound (1) is 0 ((1)-0), a compound in which the number of repeating units n is 1 ((1)-1), and a compound in which the number of repeating units n is 2 ((1)-2) from the extract. In addition, compounds in which the number of repeating units n is 3 or more ((1)-n) were obtained from the residue remaining in the filter paper thimble following Soxhlet extraction. When the mass ratio of each component was analyzed, the ratio of [(1)-1]:[(1)-2]:[(1)-n] was 1:5:94. Furthermore, Soxhlet extraction was carried out changing the extraction solvent to (a) ethanol, (b) toluene and (c) mixed solvent of toluene and ethanol (mass ratio: 10/1) in that order.

Furthermore, the numbers of repeating units n of Compounds ((1)-1) and ((1)-2) were determined using molecular sieve gel column chromatography in tetrahydrofuran solution (HLC-8220GPC manufactured by Tosoh Corp.). The results of FT-IR analysis of Compound (1) consisted of 2820 cm⁻¹, 2920 cm⁻¹ and 1060 cm⁻¹.

Unless specifically indicated otherwise, FT-IR spectra were subsequently measured directly with powder using the Spectrum One FT-IR Spectrometer manufactured by PerkinElmer Inc.

### Production Example 2

### Production of Purified Product of Compound (1)

Compound (1) obtained in Production Example 1 was subjected to Soxhlet extraction using the same method as the above-mentioned Production Example 1 of Compound 1 to obtain a purified product of Compound (1) in which compounds in which the numbers of repeating units n were 0 to 2 were removed from the above-mentioned Compound (1) (yield: 87%).

The results of FT-IR analysis of the purified product of Compound (1) consisted of 2820 cm⁻¹, 2920 cm⁻¹ and 1060 cm⁻¹.

### Production Example 3

### Production of Compound (8)

Compound (8) was obtained using the same method as Production Example 1 with the exception of changing the neopentyl glycol used in Production Example 1 to 1,4-cyclohexane dimethanol (0.53 parts) (yield: 85%).

The resulting Compound (8) was subjected to Soxhlet extraction using the same method as the above-mentioned Production Example 1 of Compound 1, and a compound in which the number of repeating units n of the above-mentioned Compound (8) is 0 ((8)-0), a compound in which the number of repeating units n is 1 ((8)-1), and a compound in which the number of repeating units n is 2 ((8) -2) were obtained from the extract. In addition, compounds in which the number of repeating units n is 3 or more ((8)-n) were obtained from the residue remaining in the filter paper thimble following Soxhlet extraction. When the mass ratio of each component was analyzed, the ratio of [(8)-1]:[(8)-2]:[(8)-n] was 1:4:95.

Furthermore, the numbers of repeating units n of Compounds ((8)-1) and ((8)-2) were determined using molecular sieve gel column chromatography in tetrahydrofuran solution (HLC-8220GPC manufactured by Tosoh Corp.). The results of FT-IR analysis of Compound (8) consisted of 2820 cm⁻¹, 2920 cm⁻¹ and 1060 cm⁻¹.

### Production Example 4

### Production of Compound (11)

Compound (11) was obtained using the same method as Production Example 1 with the exception of changing the neopentyl glycol used in Production Example 1 to 1,3-adamantane dimethanol (0.67 parts) (yield: 83%).

The resulting Compound (11) was subjected to Soxhlet extraction using the same method as the above-mentioned Production Example 1 of Compound 1, and a compound in which the number of repeating units n of the above-mentioned Compound (11) is 0 ((11)-0), a compound in which the number of repeating units n is 1 ((11)-1), and a compound in which the number of repeating units n is 2 ((11) -2) were obtained from the extract. In addition, compounds in which the number of repeating units n is 3 or more ((11)-n) were obtained from the residue remaining in the filter paper thimble following Soxhlet extraction. When the mass ratio of each component was analyzed, the ratio of [(11)-1]:[(11)-2]:[(11)-n] was 1:3:96. Furthermore, the numbers of repeating units n of Compounds ((11)-1) and ((11)-2) were determined using molecular sieve gel column chromatography in tetrahydrofuran solution (HLC-8220GPC manufactured by Tosoh Corp.). The results of FT-IR analysis of Compound (11) consisted of 2820 cm⁻¹, 2920 cm⁻¹ and 1060 cm⁻¹.

### Production Example 5

### Production of Compound (1) By-Product

A by-product of Compound (1) in the form of a phthalocyanine compound was obtained from the extract of Production Example 2 by removing the solvent under reduced pressure (yield: 10%). Furthermore, since this by-product of Compound (1) is not a pigment, but rather a liposoluble dye that is soluble in an organic solvent in the manner of chloroform, toluene or DMF, the high lightfastness characteristic of pigment was not obtained.

### Synthesis of tert-butyl Dichlorosilyl Phthalocyanine

Silane tetrachloride (1.8 parts) was dropped into a liquid dispersion of 5-t-Bu-1,3-diiminoisoindoline (1.0 part) in quinoline (10 parts) in a nitrogen atmosphere while being careful of generation of heat. Following completion of dropping, the temperature was raised to 230° C. followed by stirring for 5 hours. Following completion of the reaction, the reaction mixture was cooled to room temperature and the resulting solid was filtered under reduced pressure. The resulting solid was then dispersed in N,N-dimethylformamide (DMF) followed by raising the temperature to 80° C. The dispersion was then filtered while still hot to obtain a biaxial phthalocyanine in the form of dichlorosilyl phthalocyanine (yield: 73%).

### Production Example 6

### Production of Compound (25)

Sodium hydride (0.5 parts) was gradually added to a toluene (10 parts) solution of neopentyl glycol (0.3 parts) in a nitrogen atmosphere. Next, after gradually adding the above-mentioned tert-butyl dichlorosilyl phthalocyanine (1.0 part), the mixture was refluxed while heating for 5 hours. Following completion of the reaction, the mixture was diluted with n-hexane and the precipitated solid was filtered. The resulting solid was washed with ethanol and ion exchange water to obtain the target Compound (25) (yield: 90%).

The resulting Compound (25) was subjected to Soxhlet extraction using the same method as the above-mentioned Production Example 1 of Compound 1, and a compound in which the number of repeating units n of the above-mentioned Compound (25) is 0 ((25)-0), a compound in which the number of repeating units n is 1 ((25)-1), and a compound in which the number of repeating units n is 2 ((25) -2) were obtained from the extract. In addition, compounds in which the number of repeating units n is 3 or more ((25)-n) were obtained from the residue remaining in the filter paper thimble following Soxhlet extraction. When the mass ratio of each component was analyzed, the ratio of [(25)-1]:[(25)-2]:[(25)-n] was 1:4:85.

Furthermore, the numbers of repeating units n of Compounds ((25)-1) and ((25)-2) were determined using molecular sieve gel column chromatography in tetrahydrofuran solution (HLC-8220GPC manufactured by Tosoh Corp.). The results of FT-IR analysis of Compound (25) consisted of 2820 cm⁻¹, 2920 cm⁻¹ and 1060 cm⁻¹.

### Production Example 7

### Production of Compound (26)

Compound (26) was obtained using the same method as Production Example 6 with the exception of changing the neopentyl glycol used in Production Example 6 to 1,4-cyclohexane dimethanol (0.53 parts) (yield: 83%).

The resulting Compound (26) was subjected to Soxhlet extraction using the same method as the above-mentioned Production Example 1 of Compound 1, and a compound in which the number of repeating units n of the above-mentioned Compound (26) is 0 ((26)-0), a compound in which the number of repeating units n is 1 ((26)-1), and a compound in which the number of repeating units n is 2 ((26) -2) were obtained from the extract. In addition, compounds in which the number of repeating units n is 3 or more ((26)-n) were obtained from the residue remaining in the filter paper thimble following Soxhlet extraction. When the mass ratio of each component was analyzed, the ratio of [(26)-1]:[(26)-2]:[(26)-n] was 1:2:83.

Furthermore, the numbers of repeating units n of Compounds ((26)-1) and ((26)-2) were determined using molecular sieve gel column chromatography in tetrahydrofuran solution (HLC-8220GPC manufactured by Tosoh Corp.). The results of FT-IR analysis of Compound (26) consisted of 2820 cm⁻¹, 2920 cm⁻¹ and 1060 cm⁻¹.

### Production Example 8

### Production of Compound (27)

Compound (27) was obtained using the same method as Production Example 6 with the exception of changing the neopentyl glycol used in Production Example 6 to 1,3-adamantane dimethanol (0.67 parts) (yield: 83%).

The resulting Compound (27) was subjected to Soxhlet extraction using the same method as the above-mentioned Production Example 1 of Compound 1, and a compound in which the number of repeating units n of the above-mentioned Compound (27) is 0 ((27)-0), a compound in which the number of repeating units n is 1 ((27)-1), and a compound in which the number of repeating units n is 2 ((27) -2) were obtained from the extract. In addition, compounds in which the number of repeating units n is 3 or more ((27)-n) were obtained from the residue remaining in the filter paper thimble following Soxhlet extraction. When the mass ratio of each component was analyzed, the ratio of [(27)-1]:[(27)-2]:[(27)-n] was 1:4:90.

Furthermore, the numbers of repeating units n of Compounds ((27)-1) and ((27)-2) were determined using molecular sieve gel column chromatography in a tetrahydrofuran solution (HLC-8220GPC manufactured by Tosoh Corp.). The results of FT-IR analysis of Compound (27) consisted of 2820 cm⁻¹, 2920 cm⁻¹ and 1060 cm⁻¹.

On the other hand, the room temperature solubilities of the resulting Compound (1), purified product of Compound (1), Compound (8), Compound (11), Compound (25), Compound (26) and Compound (27) in solvents such as chloroform, toluene, DMF and water were all confirmed to be less than 0.1% by mass.

### Production of Ink (Pigment Dispersion)

### Example 1

48 parts of polyester resin and 120 parts of ethyl acetate were mixed with 6 parts of Compound (11) followed by dispersing for 3 hours with an attritor (Mitsui Mining Co., Ltd.) to obtain Pigment Dispersion (1).

### Examples 2 and 3

Pigment Dispersions (2) and (3) were obtained by producing pigment dispersions in the same manner as Example 1 with the exception of changing the ethyl acetate used in Example 1 to toluene and methyl ethyl ketone, respectively.

### Example 4

120 parts of styrene were mixed with 6 parts of Compound (11) followed by dispersing for 3 hours with an attritor (Mitsui Mining Co., Ltd.) to obtain Pigment Dispersion (4).

### Example 5

Pigment Dispersion (5) was obtained using the same procedure as Example 4 with the exception of changing the styrene used in Example 4 to cyclohexanone.

### Examples 6 to 8

Pigment Dispersions (6) to (8) were obtained using the same procedure as Example 4 with the exception of using Compound (1), the purified product of Compound (1) and Compound (8), respectively, instead of using Compound (11) used in Example 4.

### Example 9

60 parts of water were mixed into a mixture of 6 parts of Compound (11) and 1.2 parts of sodium dodecyl sulfate followed by dispersing for 3 hours with an attritor (Mitsui Mining Co., Ltd.) to obtain Pigment Dispersion (9).

### Examples 10 and 11

Pigment Dispersions (10) and (11) were obtained using the same procedure as Example 4 with the exception of using a mixture of ethyl acetate and toluene (60 parts/60 parts) and a mixture of styrene and xylene (60 parts/60 parts), respectively, instead of the styrene used in Example 4.

### Examples 12 to 14

Pigment Dispersions (12) to (14) were obtained using the same procedure as Example 4 with the exception of using Compound (25), Compound (26) and Compound (27), respectively, instead of Compound (11) used in Example 4.

### Comparative Examples 1 to 3

Pigment Dispersions (15) to (17) were obtained using the same procedure as Examples 1 to 3, respectively, with the exception of using C.I. Pigment Blue 15:3 (Cyanine Blue A-22, Dainichi Seika Color & Chemicals Mfg., Co., Ltd.) instead of Compound (11) used in Examples 1 to 3.

### Comparative Example 4

Pigment Dispersion (18) was obtained using the same procedure as Example 4 with the exception of using C.I. Pigment Blue 15:3 (Cyanine Blue A-22, Dainichi Seika Color & Chemicals Mfg., Co., Ltd.) instead of Compound (11) used in Example 4.

### Comparative Example 5

Pigment Dispersion (19) was obtained using the same procedure as Example 5 with the exception of using C.I. Pigment Blue 15:3 (Cyanine Blue A-22, Dainichi Seika Color & Chemicals Mfg., Co., Ltd.) instead of Compound (11) used in Example 5.

### Comparative Example 6

Pigment Dispersion (20) was obtained using the same procedure as Example 4 with the exception of using C.I. Pigment Blue 15:4 (Cyanine Blue 4933GN-EP, Dainichi Seika Color & Chemicals Mfg., Co., Ltd.) instead of Compound (11) used in Example 4.

### Comparative Examples 7 and 8

Pigment Dispersions (21) and (22) were obtained using the same procedures as Examples 9 and 10, respectively, with the exception of using C.I. Pigment Blue 15:3 (Cyanine Blue A-22, Dainichi Seika Color & Chemicals Mfg., Co., Ltd.) instead of Compound (11) used in Examples 9 and 10.

### Evaluation

The above-mentioned Pigment Dispersions (1) to (22) were spin-coated onto glass substrates followed by drying for 3 minutes at 90° C. to prepare coated film samples. Color development property was measured in the manner described below.

### Evaluation of Color Development Property

Color development property was evaluated by measuring the UV spectra of the resulting coated film samples (UV-3600, UV-VIS-NIR Spectrophotometer, Shimadzu Corp.).

Color development property becomes poor when Q band intensity observed at an absorption wavelength of 600 nm to 700 nm decreases. Consequently, the ratio of Q band intensity to Soret band intensity observed over a range of 200 nm to 300 nm serves as a parameter for representing color development property. Therefore, color development property was defined in the manner indicated below.

Evaluations were carried out as indicated below, and a ratio of Q band intensity to Soret band intensity of 1.30 or more was judged to constitute favorable color development property.
A: Q band intensity/Soret band intensity of 1.80 or more
B: Q band intensity/Soret band intensity of 1.30 to less than 1.80
C: Q band intensity/Soret band intensity of less than 1.30

The respective evaluation results for Examples 1 to 14 and Comparative Examples 1 to 8 are summarized in Table 1.

TABLE 1

| | | Q band | |
|---|---|---|---|
| | | intensity/ | |
| | | Soret | |
| | | band | |
| | Compound | intensity | Evaluation |
| Example 1 | Compound (11) | 1.81 | A |
| Example 2 | Compound (11) | 1.83 | A |
| Example 3 | Compound (11) | 1.82 | A |
| Example 4 | Compound (11) | 1.73 | B |
| Example 5 | Compound (11) | 1.67 | B |
| Example 6 | Compound (1) | 1.37 | B |
| Example 7 | Purified product | 1.45 | B |
| | of Compound (1) | | |
| Example 8 | Compound (8) | 1.53 | B |
| Example 9 | Compound (11) | 1.87 | A |
| Example 10 | Compound (11) | 1.72 | B |
| Example 11 | Compound (11) | 1.69 | B |
| Example 12 | Compound (25) | 6.12 | A |
| Example 13 | Compound (26) | 6.25 | A |
| Example 14 | Compound (27) | 6.28 | A |
| Comparative Example 1 | C.I. Pigment Blue 15:3 | 0.87 | C |
| Comparative Example 2 | C.I. Pigment Blue 15:3 | 0.84 | C |
| Comparative Example 3 | C.I. Pigment Blue 15:3 | 0.73 | C |
| Comparative Example 4 | C.I. Pigment Blue 15:3 | 0.77 | C |
| Comparative Example 5 | C.I. Pigment Blue 15:3 | 0.67 | C |
| Comparative Example 6 | C.I. Pigment Blue 15:4 | 0.75 | C |
| Comparative Example 7 | C.I. Pigment Blue 15:3 | 0.78 | C |
| Comparative Example 8 | C.I. Pigment Blue 15:3 | 0.69 | C |

As is clear from Table 1, inks (pigment dispersions) containing the phthalocyanine pigment having a structure represented by general formula (1) were determined to have superior color development property in comparison with the comparative examples.

### Production Color Filter Resist Composition

### Example 15

120 parts of cyclohexanone were mixed with 12 parts of Compound (11) followed by dispersing for 1 hour with an attritor (Mitsui Mining Co., Ltd.) to obtain Pigment Dispersion (23).

22 parts of the above-mentioned Pigment Dispersion (23) were slowly added to a solution of 96 parts of cyclohexanone containing 6.7 parts of an acrylic copolymer, composed of a monomer mass ratio of 40% by mass of n-butyl methacrylate, 30% by mass of acrylic acid and 30% by mass of hydroxyethyl methacrylate (weight-average molecular weight: 10,000), 1.3 parts of dipentaerythritol pentaacrylate and 0.4 parts of 2-benzyl-2-dimethylamino-1-(4-morpholinophenyl) butanone (photopolymerization initiator), followed by stirring for 3 hours at room temperature. This was then filtered with a 1.5 μm filter to obtain Color Filter Resist Composition (1) of the present invention.

The above-mentioned Color Filter Resist Composition (1) was spin-coated onto a glass substrate followed by drying for 3 minutes at 90° C. and exposing the entire surface to light to produce Color Filter (1) by post-curing at 180° C.

### Examples 16 to 18

Color Filters (2), (3) and (4) were respectively obtained using the same procedure as the production example of Example 15 with the exception of changing Compound (11) used in Example 15 to Compound (1), Purified Product of Compound (1) and Compound (8), respectively.

### Comparative Example 9

Comparative Color Filter (1) was obtained using the same procedure as Example 15 with the exception of changing Compound (11) used in Example 15 to C.I. Pigment Blue 15:3 (Cyanine Blue A-22, Dainichi Seika Color & Chemicals Mfg., Co., Ltd.).

Color development property of the resulting color filters was measured in the manner indicated below.

### Evaluation of Color Development Property

Color development property was evaluated by measuring the UV spectra of the resulting color filters (UV-3600, UV-VIS-NIR Spectrophotometer, Shimadzu Corp.).

Color development property becomes poor when Q band intensity observed at an absorption wavelength of 600 nm to 700 nm decreases. Consequently, the ratio of Q band intensity to Soret band intensity observed over a range of 200 nm to 300 nm (Q/B) serves as a parameter for representing color development property. Therefore, color development property was defined in the manner indicated below.

Evaluations were carried out as indicated below, and a ratio of Q band intensity to Soret band intensity of 1.30 or more was judged to constitute favorable color development property.
A: Q band intensity/Soret band intensity of 1.80 or more
B: Q band intensity/Soret band intensity of 1.30 to less than 1.80
C: Q band intensity/Soret band intensity of less than 1.30

The respective evaluation results for Examples 15 to 18 and Comparative Example 9 are summarized in Table 2.

TABLE 2

| | | Q band | |
|---|---|---|---|
| | | intensity/ | |
| | | Soret | |
| | | band | |
| | Compound | intensity | Evaluation |
| Example 15 | Compound (11) | 1.81 | A |
| Example 16 | Compound (1) | 1.33 | B |
| Example 17 | Purified product | 1.42 | B |
| | of Compound (1) | | |
| Example 18 | Compound (8) | 1.51 | B |
| Comparative Example 9 | C.I. Pigment Blue 15:3 | 0.59 | C |

As is clear from Table 2, color filters containing the phthalocyanine pigment having a structure represented by general formula (1) were determined to have superior color development property in comparison with the comparative example.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-183475, filed Aug. 22, 2012, which is hereby incorporated by reference herein in its entirety.

1. A phthalocyanine pigment having a structure represented by general formula (1): 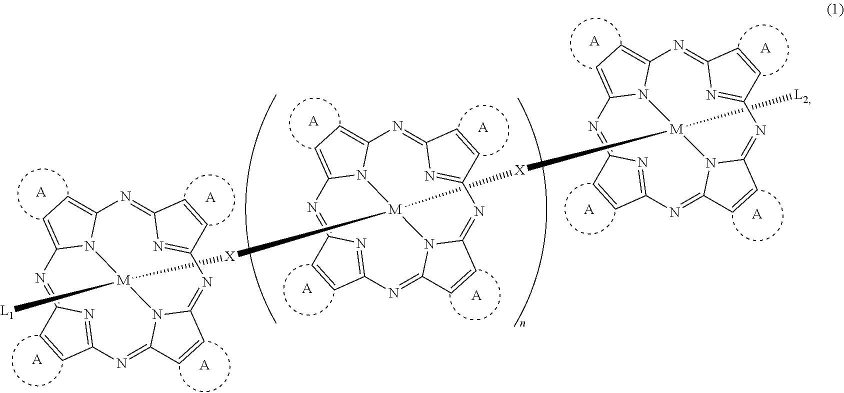
wherein, in the general formula (1):
X represents —O—CH₂—R¹—CH₂—O—;
R¹ represents
a monocyclic or polycyclic cyclic hydrocarbon group
or
—CR²R³—;
R² and R³ represent an alkyl group; 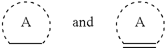
each independently represent
a substituted or unsubstituted aryl ring
or
a heterocycle containing one or two nitrogen atoms;
M represents a metal atom selected from the group consisting of Si, Ge and Sn;
L₁ and L₂ each independently represent a halogen atom, a hydroxyl group, —O—CH₂—R⁴—CH₂—OR⁸, —O—CH₂—R⁵—OR⁹ or —OR¹⁰;
R⁴ and R⁵ represent
a monocyclic or polycyclic cyclic hydrocarbon group
or
—CR⁶R⁷—;
R⁶ and R⁷ represent an alkyl group;
R⁸ to R¹⁰ each independently represent a hydrogen atom, a methyl group or a trimethylsilyl group; and
n represents an integer of 1 or more.

2. The phthalocyanine pigment according to claim 1, wherein R¹ in the general formula (1) is a monocyclic or polycyclic cyclic hydrocarbon group.

3. The phthalocyanine pigment according to claim 2, wherein R¹ in the general formula (1) is a norbornanediyl group, a norbornenediyl group or an adamantanediyl group.

4. The phthalocyanine pigment according to claim 1, wherein 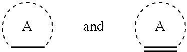
in the general formula (1) are each independently a substituted or unsubstituted benzene ring, pyridine ring or pyrazine ring.

5. The phthalocyanine pigment according to claim 1, wherein 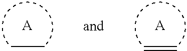
in the general formula (1) are each independently a substituted or unsubstituted benzene ring.

6. The phthalocyanine pigment according to claim 1, wherein 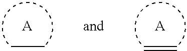
in the general formula (1) are each independently a benzene ring having a tert-butyl group.

7. The phthalocyanine pigment according to claim 1, wherein M in the general formula (1) is Si.

8. A pigment dispersion comprising a dispersion medium and the phthalocyanine pigment according to claim 1.

9. An ink comprising the pigment dispersion according to claim 8.

10. A color filter resist composition comprising at least one of a binder resin and polymerizable polymer, and the phthalocyanine pigment according to claim 1.
